(19) United States
(12) Patent Application Publication
(10) Pub. No.: US 2006/0037737 A1
(43) Pub. Date: Feb. 23, 2006

(54) Heat dissipation apparatus and vapor chamber thereof

(75) Inventors: Yency Chen, Taoyuan Hsien (TW); Chi-Feng Lin, Taoyuan Hsien (TW); Chin-Ming Chen, Taoyuan Hsien (TW)

Correspondence Address: BIRCH STEWART KOLASCH & BIRCH, PO BOX 747, FALLS CHURCH, VA, 22040-0747, US

(73) Assignee: Delta Electronics, Inc.

(21) Appl. No.: 11/080,464

(22) Filed: Mar. 16, 2005

(30) Foreign Application Priority Data
Aug. 18, 2004 (TW) 93124811

(51) Int. Cl. H05K 7/20

(52) U.S. Cl. 165/104.26; 361/700

(57) ABSTRACT

A heat dissipation apparatus and a vapor chamber thereof. The heat dissipation apparatus comprises a heat sink and a vapor chamber for dissipating heat from a heat source of an electric device. The vapor chamber comprises a heat-absorption region, a heat-dissipation region, a working fluid, a wick structure and at least one buffer region. The working fluid in the heat-absorption region is vaporized while absorbing heat in the heat-absorption region from the heat source, and the vaporized working fluid condenses in the heat-dissipation region after latent heat thereof is released. The capillarity of the wick structure drives the working fluid returning to the heat-absorption region from the heat-dissipation region, and the buffer regions include a reservoir for accessing the working fluid. The heat-dissipation apparatus equipped with a vapor chamber having buffer regions can reduce entire weight and shorten distance during heat conduction so that heat dissipation efficiency is increased.

This Non-provisional application claims priority under U.S.C. § 119(a) on Patent Application No(s). 093124811 filed in Taiwan, Republic of China on Aug. 18, 2004, the entire contents of which are hereby incorporated by reference.

### BACKGROUND

The invention relates to a heat dissipation apparatus, and in particular to a heat dissipation apparatus providing a vapor chamber for dissipating heat from a heat source.

With the progression of transistor placement techniques, a large number of transistors can be simultaneously placed on an electronic element per unit area. As a result, heat is correspondingly produced. Switch loss caused by alternating transistors between ON and OFF is a partial cause of heat generation under high working frequency conditions in the present electronic element. Additionally, with enhanced chipset speed, heat generated thereby is correspondingly increased in proportion to the clock pulse increment. If heat generated therefrom cannot be efficiently dissipated, it may damage chipset and reduce chipset life and operating speed.

In FIG. 1A, a conventional heat-dissipation apparatus 10A is used for dissipating heat from a heat source 11, e.g., a heat-generating electronic element such as a CPU. The heat-dissipation apparatus 10A includes a metallic block 12 and a heat sink 15. The block 12 is disposed directly on the heat source 11. The heat sink 15 overlies and surrounds the block 12, so that heat can be transmitted from the heat source 11 to the heat sink 15 via the block 12. The heat sink 15 has a plurality of fins for increasing the effect of heat dissipation. Additionally, a fan 16 is further provided for enhancing cooling speed.

However, the distance L1 from the surface of the block 12 to top of the heat sink 15 is too long to provide good heat conduction efficiency. Further, the block 12, particularly when made of solid copper, is not economical and is unsuitable due to the weight thereof which may damage the delicate heat source 11 and increases the total weight of the product.

In FIG. 1B, another conventional heat-dissipation apparatus 10B includes a plate-like heat pipe 13 and the heat sink 15. The plate-like heat pipe 13 can be either directly attached on the heat source 11 or attached to the heat source 11 after a copper base plate-like is attached to the plate-like heat pipe 13. The heat sink 15 overlies and surrounds the plate-like heat pipe 13, so that heat can be transmitted from the heat source 11 to the heat sink 15 via the plate-like heat pipe 13.

The plate-like heat pipe 13, a type of heat piping structure, typically comprises a chamber, a wick structure and a working fluid. The working fluid absorbs heat from the heat source 11 and becomes vaporized. And then the vaporized working fluid condenses into liquid after the latent heat of the vaporized working fluid is released. The liquid working fluid then flows back to the heated regions of the heat pipe 13 via capillary force provided by the wick structure. The speed of heat dissipation and amount of conductive heat dissipated by the heat-dissipation apparatus 10B with the plate-like heat pipe 13 is twenty-five to one hundred times faster when compared with the heat-dissipation apparatus 10A with the solid copper block 12.

However, the distance L2 from the surface of the heat pipe 13 to top of the heat sink 15 is too long to provide good heat conduction efficiency. Also, the speed of heat transferred to the surface of the heat pipe 13 from the wick structure is generally slow as the wick structure is thick. Although a wick structure with reduced thickness can facilitate the speed of heat conduction, the heated regions inevitably dry out once the working fluid supplement is insufficient when heat from the heat source and rate of evaporation of the working fluid is high. As the result, it causes damage to the plate-like heat pipe 13 and the heat-dissipation apparatus 10B can not be used anymore.

### SUMMARY

The invention provides a heat dissipation apparatus utilizing a vapor chamber having a thin wick structure and buffer regions to reduce product weight and conduction distance and increase the rate of heat dissipation.

The vapor chamber of the invention is used for transferring heat from a heat source to a heat sink. The vapor chamber includes a heat-absorption region, a heat-dissipation region, a working fluid, a wick structure and at least one buffer region. The heat-absorption region contacts the heat source and the heat-dissipation region contacts the heat sink. The working fluid is sealed within the vapor chamber for transferring heat from the heat-absorption region to the heat-dissipation region. The wick structure is used for driving the working fluid returning to the heat-absorption region from the heat-dissipation region. The buffer region comprises a reservoir for accessing the working fluid. The working fluid is adequately supplied to the heat-absorption region from the buffer region. The vapor chamber includes a bottom surface attached to a top surface of the base and a top surface contacting the heat sink. The bottom surface of the vapor chamber is larger than, equal to, or smaller than the top surface of the vapor chamber. The vapor chamber includes a reduced sectional area varying from the bottom surface to the top surface thereof. A sectional area of the vapor chamber has a shape of an ellipse, hemicycle arc, rectangle, triangle, quadrilateral, trapezoid, pentagon, hexagon, octagon, equilateral polygon or scalene polygon.

Another aspect of the invention provides a heat dissipation apparatus applied to a heat-generating electronic element. The heat dissipation apparatus comprises a heat sink and a vapor chamber. The vapor chamber transfers heat from the heat-generating electronic element to the heat sink. The vapor chamber includes a heat-absorption region, a heat-dissipation region, a working fluid, a wick structure and at least one buffer region. The heat-absorption region contacts the heat source and the heat-dissipation region contacts the heat sink. The working fluid is sealed within the vapor chamber for transferring heat from the heat-absorption region to the heat-dissipation region. The wick structure drives the working fluid returning to the heat-absorption region from the heat-dissipation region. The buffer region includes a reservoir for accessing the working fluid. The working fluid is adequately supplied to the heat-absorption region from the buffer region. The vapor chamber includes a bottom surface attached to a top surface of the base and a top surface contacting the heat sink. The bottom surface of the vapor chamber is larger than, equal to, or smaller than the top surface of the vapor chamber. The vapor chamber includes a reduced sectional area varying from the bottom surface to the top surface thereof. A sectional area of the vapor chamber can be an ellipse, hemicycle arc, rectangle, triangle, quadrilateral, trapezium, pentagon, hexagon, octagon, equilateral polygon or scalene polygon.

### DESCRIPTION OF THE DRAWINGS

The invention can be more fully understood by reading the subsequent detailed description and examples with references made to the accompanying drawings, wherein:

FIGS. 1A and 1B are two schematic views of two different conventional heat-dissipation apparatuses.

FIG. 2A is a schematic view of a heat-dissipation apparatus according to a preferred embodiment of the invention.

FIG. 2B is a schematic view of another heat-dissipation apparatus according to the preferred embodiment of the invention.

FIG. 2C is a schematic view of the vapor chamber of FIG. 2A.

FIGS. 3A, 3B, and 3C are schematic views of three heat-dissipation apparatuses equipped with different vapor chamber.

### DETAILED DESCRIPTION

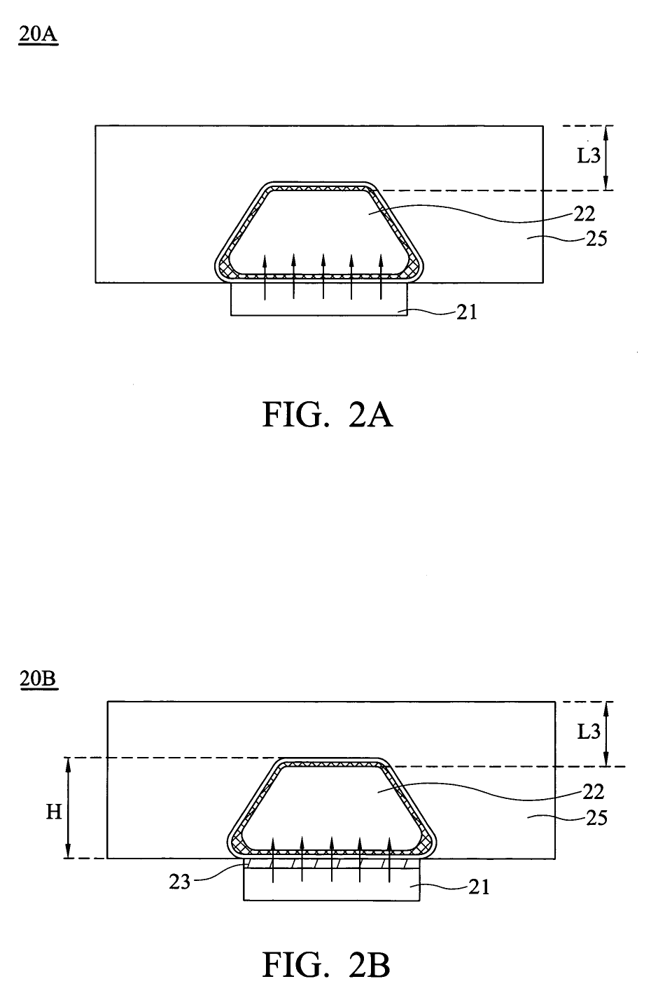

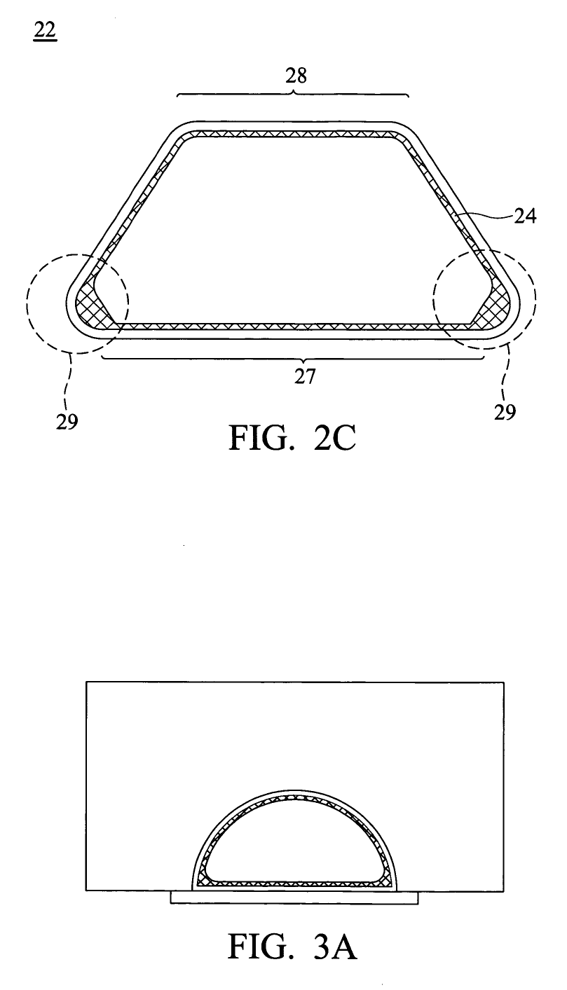

FIG. 2A is a schematic view of a heat-dissipation apparatus 20A of the invention. The heat-dissipation apparatus 20A is disposed on a heat source 21, e.g., a heat-generating electronic element such as a CPU, transistor, server, graphic card, hard disk, power supply, vehicle control system, multimedia electronic apparatus, wireless corresponding station, advanced game machine (PS3, XBOX, Nintendo) and the like. The heat-dissipation apparatus 20A includes a vapor chamber 22 and a heat sink 25. The vapor chamber 22 is directly disposed on the heat source 21 and the heat sink 25 is disposed on and around the vapor chamber 22. Heat generated from the heat source 21 is absorbed by the vapor chamber 22 and then transferred to the heat sink 25 or other related device (not shown). The heat sink 25 includes several fins, and the shape of the heat sink 25 is accordingly altered for accommodating the vapor chamber 22. Further, an additional fan (not shown) can be additionally provided to increase the efficiency of heat dissipation according the design and volume of total space.

In FIG. 2A, the vapor chamber 22 is directly disposed on the heat source 21, however, the vapor chamber 22 can be disposed on the heat source 21 via a metallic base. Referring to FIG. 2B, which is a schematic view of another heat-dissipation apparatus 20B according to the preferred embodiment of the invention. Except for the vapor chamber 22 and the heat sink 25, the heat-dissipation apparatus 20B further includes a base 23 disposed between the vapor chamber 22 and the heat source 21, so that the heat-absorption region of the vapor chamber 22 indirectly contacts the heat source 21. The vapor chamber 22 and the base 23 can be fabricated by welding, or the vapor chamber 22 and the base 23 are connected by applying a soldering paste, a grease or the like therebetween.

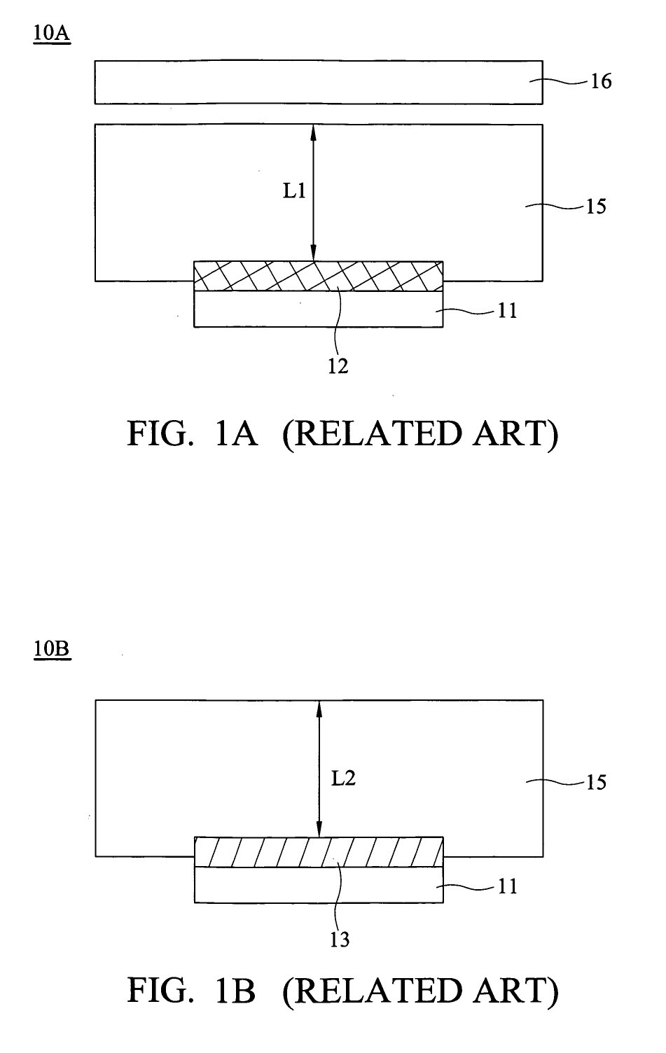

The vapor chamber 22 has a larger volume compared with the conventional plate-like heat pipe, however, there is no additional volume is created for the entire heat-dissipation apparatus 20A/20B because the vapor chamber 22 is accommodated within the heat sink 25. Consequentially, the height H of the vapor chamber 22 is relatively greater than that of the conventional plate-like heat pipe 13. Thus, the distance L3 from the top surface of the vapor chamber 22 to the top of the heat sink 25 is correspondingly shortened. In comparison to the distance L1/L2 in FIG. 1A/1B, the distance L3 in FIG. 2B is less than the distance L1/L2. The heat conduction distance is reduced, and therefore, the rate of heat dissipation is improved.

The vapor chamber 22 includes a bottom surface contacting the top of the base 23 and a top surface contacting the heat sink 25. Considering the heat conduction gradient, the bottom surface of the vapor chamber 22 can be larger than, equal to or smaller than the top surface of the vapor chamber 22. Alternatively, the vapor chamber 22 can has a reduced sectional area varying from the bottom surface to the top surface thereof.

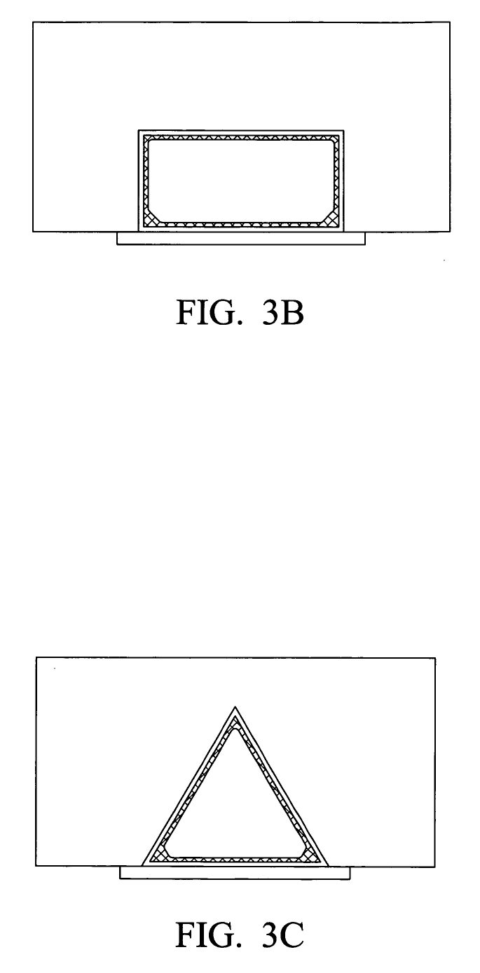

It is to be understood that the shape of the vapor chamber 22 of the invention is not limited to the disclosed embodiments only if heat conduction distance can be shortened, but, on the contrary, is intended to cover various modifications and equivalent arrangements included within the spirit and scope of the appended claims. For example, referring to FIGS. 3A, 3B, and 3C, which show three heat-dissipation apparatuses equipped with different vapor chamber according to the preferred embodiments. The section of the vapor chamber can be a trapezoid (FIG. 2A), ellipse, hemicycle arc (FIG. 3A), rectangle (FIG. 3B), triangle (FIG. 3C), quadrilateral, trapezium, pentagon, hexagon, octagon, equilateral polygon or scalene polygon.

Further, referring to both FIG. 2A and FIG. 2C, FIG. 2C is a schematic view of the vapor chamber of FIG. 2A. The vapor chamber 22 includes a wick structure 24 and a working fluid is sealed within the vapor chamber 22 for transferring heat from the heat-absorption region to the heat-dissipation region. In order to solve the problem occurred in the wick structure of the related art in FIGS. 1A and 1B, the invention provides the wick structure 24 with a smaller thickness than that of the related art. Thus, rate of heat conducting from the wick structure 24 to the heat source 21 is greatly increased, so that heat can be quickly transferred to the heat sink 25 or exterior of the vapor chamber 22 via the vapor chamber 22. In addition, it is more economical on a material used for manufacturing the wick structure 24 than that of the related art, and therefore the weight of the heat-dissipation apparatus disposed on the heat source can be reduced.

The thin wick structure 24 includes a heat-absorption region 27, a heat-dissipation region 28 and at least one buffer region 29. The heat-absorption region partially contacts the heat source 21, and the heat-dissipation region 28 partially contacts the heat sink 25. The working fluid in the heat-absorption region 27 is vaporized as absorbing heat from the heat source 21, and the working fluid in the heat-dissipation region 28 is condensed after latent heat thereof is released. The working fluid then flows back to the heat-absorption region 27 from the heat-dissipation region 28 via capillary force of the wick structure 24.

As the wick structure 24 of the invention is relatively thinner than that of the related art in FIG. 1A/1B, the wick structure 24 has a relatively smaller volume for containing the working fluid. Nevertheless, at least one buffer region 29 of the wick structure 24 provides a reservoir for accessing the working fluid, so that the amount of the working fluid in the vapor chamber 22 increases. Thus, the working fluid is adequately and constantly supplied to the heat-absorption region 27 from the buffer region 29 even if heat from the heat source 21 and rate of evaporation of the working fluid is high. Dried heated regions of the heat pipe 13 of FIG. 1B is prevented based on the operative principles of the invention.

Moreover, because the rate of heat transferred from the thin wick structure 24 to the exterior of the vapor chamber 22 increases, heat dissipation efficiency of the heat-dissipation apparatus is increased.

In other preferred embodiments, the material of the vapor chamber can be plastic, metal, alloy or non-metal material, and the working fluid can be an inorganic compound, water, alcohol, liquid metal, ketone, refrigerant or an organic compound. The wick structure can be formed by a method such as sintering, adhesion, filling or deposition. The wick structure can be a mesh wick, a fiber wick, a sinter wick a groove wick, or a combination thereof.

While the invention has been described with respect to preferred embodiment, it is to be understood that the invention is not limited thereto the disclosed embodiments, but, on the contrary, is intended to accommodate various modifications and equivalent arrangements included within the spirit and scope of the appended claims.

What is claimed is:

1. A vapor chamber used for transferring heat from a heat source to a heat sink, comprising:
a heat-absorption region for contacting the heat source;
a heat-dissipation region for contacting the heat sink;
a working fluid sealed within the vapor chamber for transferring heat from the heat-absorption region to the heat-dissipation region;
a wick structure for driving the working fluid returning to the heat-absorption region from the heat-dissipation region; and
at least one buffer region comprising a reservoir for accessing the working fluid.

2. The vapor chamber as claimed in claim 1, wherein the working fluid is adequately supplied to the heat-absorption region from the buffer region.

3. The vapor chamber as claimed in claim 1, further comprising a base disposed on the heat source, so that the heat-absorption region of the vapor chamber contacts the heat source via the base.

4. The vapor chamber as claimed in claim 3, wherein the base and the vapor chamber are assembled by welding, and the vapor chamber and the heat sink are assembled by welding.

5. The vapor chamber as claimed in claim 3, wherein a soldering paste or a grease is disposed between the base and the vapor chamber, and is disposed between the vapor chamber and the heat sink.

6. The vapor chamber as claimed in claim 3, wherein the vapor chamber comprises a bottom surface attached to a top surface of the base and a top surface contacting the heat sink.

7. The vapor chamber as claimed in claim 6, wherein the bottom surface of the vapor chamber is larger than, equal to or smaller than the top surface of the vapor chamber.

8. The vapor chamber as claimed in claim 6, wherein the vapor chamber comprises a reduced sectional area varying from the bottom surface to the top surface of the vapor chamber.

9. The vapor chamber as claimed in claim 1, wherein a sectional area of the vapor chamber has a shape of ellipse, hemicycle arc, rectangle, triangle, quadrilateral, trapezium, pentagon, hexagon, octagon, equilateral polygon or scalene polygon.

10. The vapor chamber as claimed in claim 1, wherein the wick structure comprises mesh wick, fiber wick, sinter wick, groove wick or a combination thereof.

11. The vapor chamber as claimed in claim 1, wherein the wick structure is formed by sintering, gluing, filling, deposition or a combination thereof.

12. A heat dissipation apparatus applied to a heat-generating electronic element, comprising:
a heat sink; and
a vapor chamber used for transferring heat from the heat-generating electronic element to the heat sink, comprising:
a heat-absorption region for contacting the heat-generating electronic element;
a heat-dissipation region for contacting the heat sink;
a working fluid sealed within the vapor chamber for transferring heat from the heat-absorption region to the heat-dissipation region;
a wick structure for driving the working fluid returning to the heat-absorption region from the heat-dissipation region; and
at least one buffer region comprising a reservoir for accessing the working fluid.

13. The heat dissipation apparatus as claimed in claim 12, wherein the working fluid is adequately supplied to the heat-absorption region from the buffer region.

14. The heat dissipation apparatus as claimed in claim 12, further comprising a base disposed on the heat-generating electronic element, so that the heat-absorption region of the vapor chamber contacts the heat-generating electronic element via the base.

15. The heat dissipation apparatus as claimed in claim 14, wherein the base and the vapor chamber are assembled by welding, and the vapor chamber and the heat sink are assembled by welding.

16. The heat dissipation apparatus as claimed in claim 14, wherein a soldering paste or a grease is disposed between the base and the vapor chamber, and is disposed between the vapor chamber and the heat sink.

17. The heat dissipation apparatus as claimed in claim 14, wherein the vapor chamber comprises a bottom surface attached to a top surface of the base and a top surface contacting the heat sink.

18. The heat dissipation apparatus as claimed in claim 17, wherein the bottom surface of the vapor chamber is larger than, equal to or smaller than the top surface of the vapor chamber.

19. The heat dissipation apparatus as claimed in claim 17, wherein the vapor chamber comprises a reduced sectional area varying from the bottom surface to the top surface of the vapor chamber.

20. The heat dissipation apparatus as claimed in claim 12, wherein a sectional area of the vapor chamber has a shape of ellipse, hemicycle arc, rectangle, triangle, quadrilateral, trapezium, pentagon, hexagon, octagon, equilateral polygon or scalene polygon.
